(19) United States
(12) Patent Application Publication
(10) Pub. No.: US 2019/0295643 A1
(43) Pub. Date: Sep. 26, 2019

(54) SEMICONDUCTOR MEMORY DEVICE

(71) Applicant: TOSHIBA MEMORY CORPORATION, Tokyo (JP)

(72) Inventor: Takayuki TSUKAMOTO, Yokkaichi Mie (JP)

(73) Assignee: TOSHIBA MEMORY CORPORATION, Tokyo (JP)

(21) Appl. No.: 16/128,439

(22) Filed: Sep. 11, 2018

(30) Foreign Application Priority Data
Mar. 22, 2018 (JP) 2018-054497

(51) Int. Cl. G11C 13/00

(52) U.S. Cl. CPC G11C 13/0064; G11C 13/004; G11C 13/0007; G11C 2213/31; G11C 2213/79; G11C 2213/33; G11C 2213/34; G11C 2213/71; G11C 2213/32

(57) ABSTRACT

According to one embodiment, a semiconductor memory device includes a word line, a bit line crossing the word line, a memory cell, and a controller. The memory cell is provided at an intersection between the word and bit lines and includes a variable resistive element. The controller controls a voltage application and a read operation to the memory cell. The controller performs a first operation of applying a first voltage to the memory cell, and a first verification of verifying whether a resistance of the memory cell becomes equal to a first value or greater after the first operation. The controller performs a second operation of applying to the memory cell a second voltage set based on the first voltage, when the resistance of the memory cell becomes equal to the first value or greater in the first verification.

### CROSS-REFERENCE TO RELATED APPLICATIONS

This application is based upon and claims the benefit of priority from the Japanese Patent Application No. 2018-054497, filed Mar. 22, 2018, the entire contents of which are incorporated herein by reference.

### FIELD

Embodiments described herein relate generally to a semiconductor memory device.

### BACKGROUND

A resistance change memory, such as a ReRAM (resistive random access memory), is known as a type of semiconductor memory device. A memory cell of the ReRAM includes a resistance change layer, in which the resistance value changes by application of a voltage. High integration and cost reduction are expected to be achieved by stacking memory cells of the ReRAM to provide a three-dimensional structure.

### BRIEF DESCRIPTION OF THE DRAWINGS

FIG. 1 is a block diagram showing a configuration of a semiconductor memory device according to an embodiment.

FIG. 2 is a perspective view showing a memory block of the semiconductor memory device according to the embodiment.

FIG. 3 is a top view showing the memory block of the semiconductor memory device according to the embodiment.

FIG. 4 is a circuit diagram of the memory cell array in the semiconductor memory device according to the embodiment.

FIG. 5 is a circuit diagram of a memory cell array in another configuration of the semiconductor memory device according to the embodiment.

FIG. 6 is a diagram showing voltages in a reset operation, a set operation, and a read operation of the embodiment.

FIG. 7 is a flowchart showing the reset operation of the embodiment.

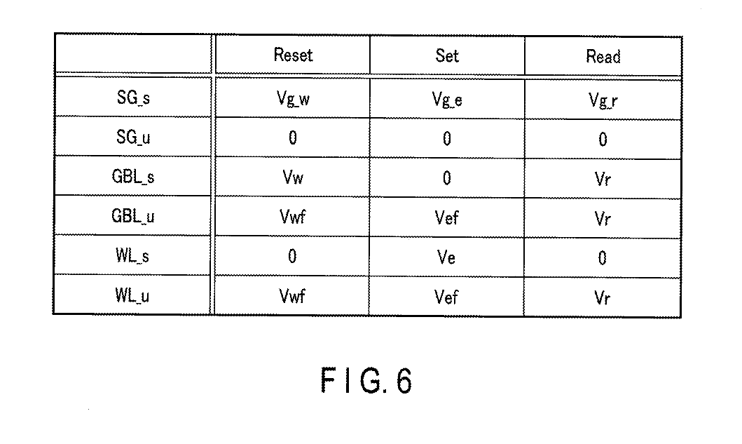

FIG. 6 is a diagram showing a change in current in a verification read by application of a reset voltage in the embodiment.

FIG. 9 is a diagram showing a change in resistance of a memory cell by application of the reset voltage in the embodiment.

FIG. 10 is a diagram showing a reset voltage and a verification voltage applied to a memory cell in the reset operation of the embodiment.

FIG. 11 is a waveform diagram showing voltages of a bit line and a word line when the reset voltage is applied in the embodiment.

FIG. 12 is a waveform diagram showing voltages of the bit line and the word line when the reset voltages are consecutively applied in the embodiment.

### DETAILED DESCRIPTION

In general, according to one embodiment, a semiconductor memory device includes a word line, a bit line, a memory cell, and a controller. The bit line is crossing the word line. The memory cell is provided at an intersection between the word line and the bit line and includes a variable resistive element. The controller is configured to control a voltage application and a read operation with respect to the memory cell. The controller performs a first operation of applying a first voltage to the memory cell, and a first verification of verifying whether a resistance of the memory cell becomes equal to a first value or greater after the first operation. The controller performs a second operation of applying to the memory cell a second voltage set based on the first voltage, when the resistance of the memory cell becomes equal to the first value or greater in the first verification.

An embodiment will be described with reference to the accompanying drawings. In the description below, structural elements having the same functions and configurations will be denoted by the same reference symbols. It should be noted that the drawings are schematic or conceptual, and that the dimensions and scales of the drawings, etc. are not necessarily the same as those of the actual products. Each of the embodiments described below merely shows an exemplary apparatus and method that implements the technical ideas of the embodiments. The element materials, shapes, structures, arrangements etc. are not limited to those described below.

In the following, a resistance change memory is described, in which a variable resistive element whose resistance value changes by application of a voltage or current flow is used as a storage element. The resistance change memory is also referred to as the ReRAM (resistive random access memory).

### 1. Embodiment

A semiconductor memory device according to the embodiment will be described.

1.1 Configuration of Semiconductor Memory Device.

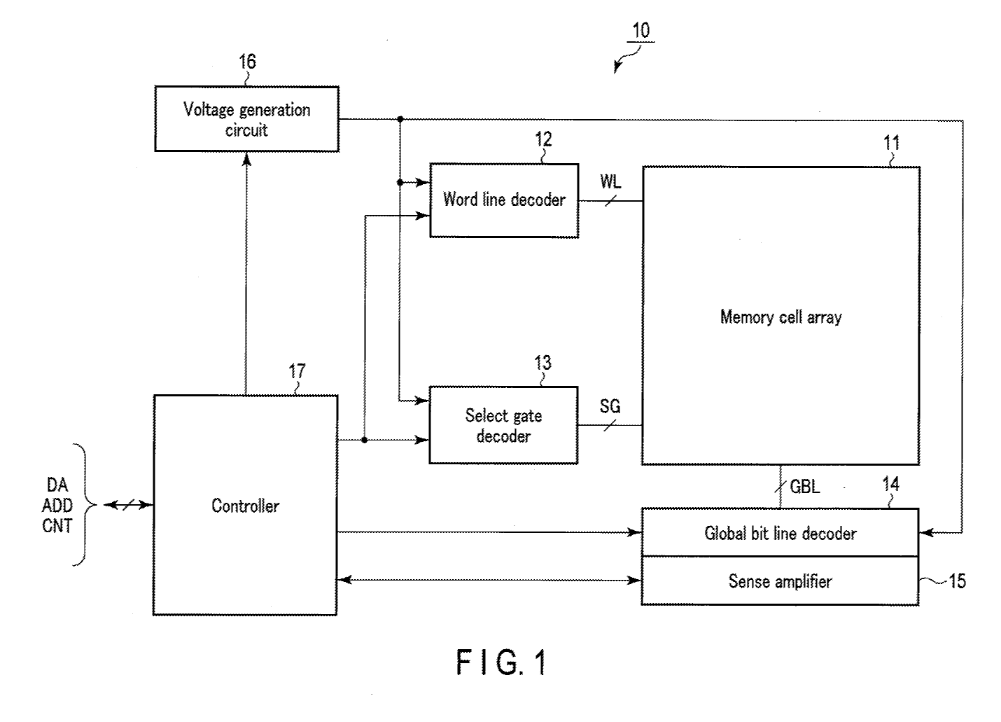

FIG. 1 is a block diagram showing a configuration of a semiconductor memory device 10 according to the embodiment. The semiconductor memory device 10 includes a memory cell array 11, word line decoder 12, a select gate decoder 13, a global bit line decoder 14, a sense amplifier 15, a voltage generation circuit 16, and a controller 17.

The memory cell array 11 includes a plurality of variable resistive elements (or resistance change elements) as storage elements. Each variable resistive element is connected to a bit line BL and a word line WL. The memory cell array 11 includes a plurality of select transistors respectively corresponding to a plurality of bit lines BL. The bit lines are connected to a global bit line GBL via the select transistors. The gates of the select transistors are connected to the select gate line SG. The specific configuration of the memory cell array 11 will be described later.

The word line decoder 12 is connected to a plurality of word lines WL. The word line decoder 12 includes a word line select circuit and a word line driver. The word line decoder 12 receives a row address from the controller 17, and selects a word line based on the row address. The word line decoder 12 applies a voltage necessary for a reset operation, a read operation, and a set operation for data to both a select word line and a non-select word line.

The select gate decoder 13 is connected to a plurality of select gate lines SG. The select gate decoder 13 includes a select gate line selection circuit and a select gate line driver. The select gate decoder 13 receives a sheet address from the controller 17, and selects a select gate line SG based on the sheet address.

The global bit line decoder (hereinafter also referred to as the bit line decoder) 14 is connected to a plurality of global bit lines GBL. The bit line decoder 14 includes a global bit line selection circuit and a global bit line driver. The bit line decoder 14 receives a column address from the controller 17, and selects a global bit line GBL based on the column address. The bit line decoder 14 applies a voltage necessary for a data reset operation, a data read operation, and a data set operation to a select global bit line GBL and a non-select global bit line GBL.

The sense amplifier 15 senses and amplifies data read out from the variable resistive element to the global bit line GBL in a verification read, either in a reset operation or a read operation. The data read out by the sense amplifier 15 is transmitted to the controller 17.

The voltage generation circuit 16 generates a plurality of voltages necessary for a reset operation, a read operation, and a set operation for data. The voltage generated by the voltage generation circuit 16 is supplied to the word line decoder 12, the select gate decoder 13, and the global bit line decoder 14.

The controller 17 performs the overall control of the operation of the semiconductor memory device 10. The controller 17 is connected to an external apparatus, such as a host apparatus, through a bus. The controller 17 receives data DA, an address ADD, a control signal CNT, or the like from the host apparatus. The controller 17 executes the reset operation, the read operation, and the set operation using the data DA, the address ADD, and the control signal CNT.

1.1.1 Configuration of Memory Cell Array 11

Now, the configuration of the memory cell array 11 shown in. FIG. 1 will be described. The memory cell array 11 includes a plurality of memory blocks MB. Each of the memory blocks MB includes a plurality of memory cells. Each memory cell stores data in a nonvolatile manner. The plurality of global bit lines GBL are connected to the plurality of memory blocks MB.

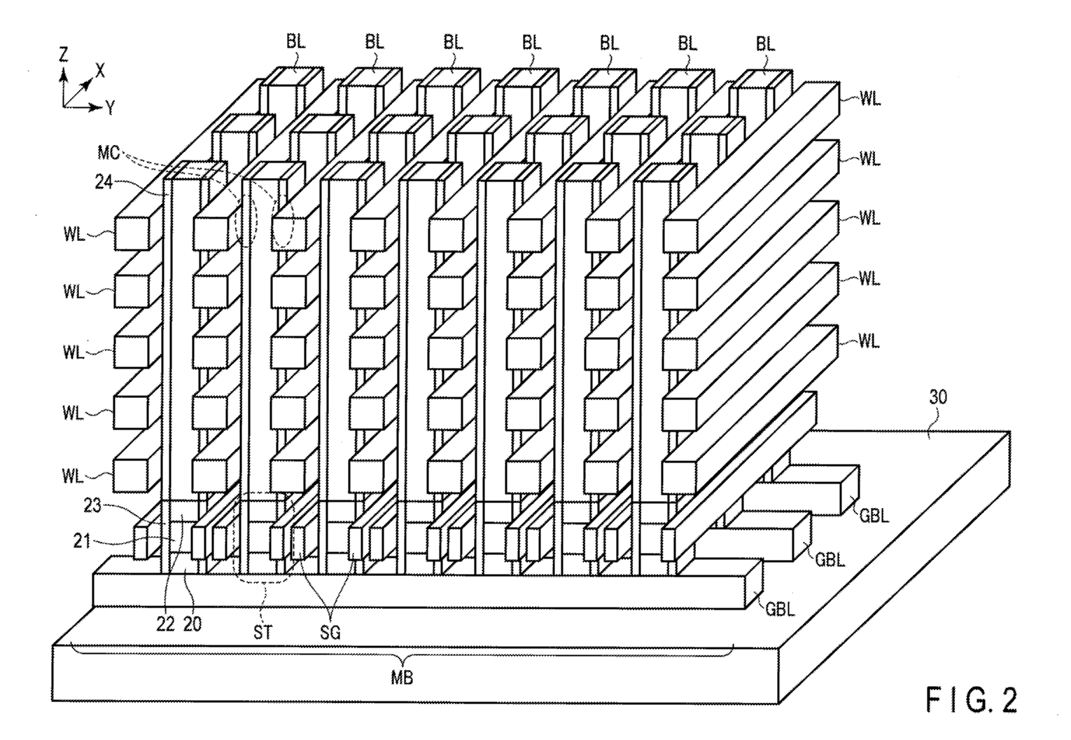

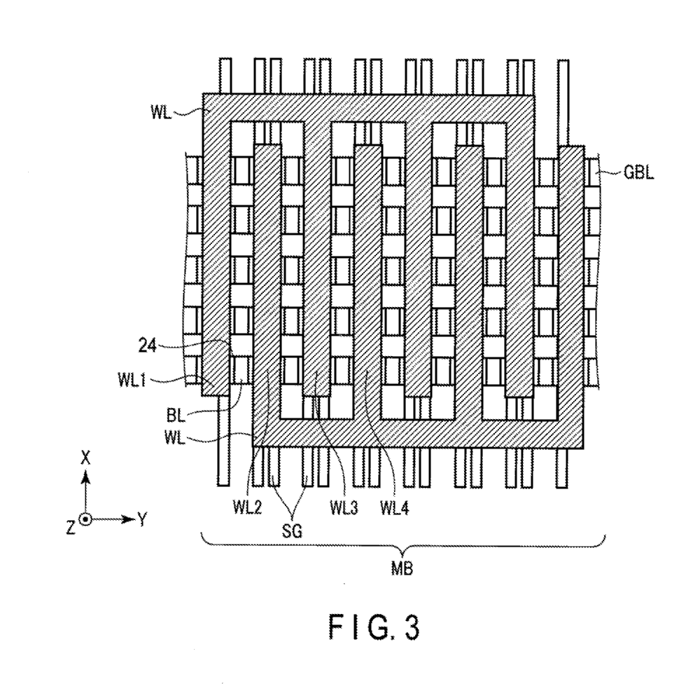

Next, a configuration of the memory block MB of the memory cell array 11 will be described with reference to FIG. 2 and FIG. 3. FIG. 2 is a perspective view of the memory block MB. FIG. 3 is a top view of the memory block MB. In FIG. 3, shaded areas represent a layout of the word lines WL. In FIG. 2 and FIG. 3, two directions perpendicular to each other and parallel to a semiconductor substrate surface are defined as X direction and Y direction, and a direction perpendicular to X direction and Y direction (XY plane) is defined as Z direction.

As shown in FIG. 2, a layer of a plurality of global bit lines GBL extending in Y direction and aligned along X direction is provided above a semiconductor substrate, for example, a silicon substrate 30. A layer of a plurality of select gate lines SG extending in X direction and aligned along Y direction is provided above the global bit lines GBL. A layer of a plurality of word lines WL extending in X direction and aligned along Y direction is provided above the select gate lines SG. A plurality of layers, each including the plurality of word lines WL, are stacked along Z direction. A plurality of insulating layers are provided respectively between two of the plurality of stacked wiring layers.

A plurality of bit lines BL extending in Z direction are interposed between every two word lines WL adjacent in. Y direction. The bit lines BL are aligned along X direction, and a plurality of insulating layers are interposed between every two bit lines BL adjacent to each other in X direction. The bit lines BL are connected to the global bit line GBL via the select transistors ST

A resistance change layer 24 as a variable resistive element described above is interposed between the word line WL and the bit line BL. The resistance change layer 24 functions as a memory cell MC storing data in an intersection portion between the word line WL and the bit line BL.

As shown in FIG. 3, the word lines WL included in the wiring layer of the same level include, for example, a first word line WL1, a second word line WL2, a third word line WL3, and a fourth word line WL4, each extending in X direction. The first word line WL1 and the second word line WL2 are adjacent to each other in Y direction. The second word line WL2 and the third word line WL3 are adjacent to each other in Y direction. The third word line WL3 and the fourth word line WL4 are adjacent to each other in Y direction. The first word line WL1 and the third word line WL3 are electrically connected, and the second word line WL2 and the fourth word line WL4 are electrically connected. In other words, the memory cell array 11 includes two word lines WL that form two comb structures, and a plurality of word line portions (straight portions of the comb structures) extending in X direction (of the two comb structures) are alternately arranged. Although not shown, as another example, the first word line WL1 and the fourth word line WL4 may be electrically connected, and the second word line. WL2 and the third word line WL3 may be electrically connected.

Specifically, of the word lines WL arranged from the left side of FIG. 3, the first word line WL1 and the third word line WL3 are connected in common, and the same voltage is applied to the commonly-connected word lines. The second word line WL2 and the fourth word line WL4 are connected in common, and the same voltage is applied to the commonly-connected word lines. The combined structure formed by the first word line WL1 and the third word line WL3, which are electrically connected, is electrically isolated from the combined structure formed by the second word line WL2 and the fourth word line WL4, which are electrically connected. Different voltages can be applied to the structures isolated from each other. In the following description, even-numbered (second, fourth, etc.) word lines are referred to as a word line group WLcomb_a, whereas odd-numbered (first, third, fifth, etc.) word lines are referred to as a word line group WLcomb_b. In the case where the two groups need not be distinguished, the word line group is simply referred to as the word line group WLcomb.

FIG. 3 shows eight word lines, five global bit lines GBL, and 45 bit lines BL; however this is a mere example. The number of the lines may be appropriately adopted.

As shown in FIG. 2, the select transistors ST are provided on the global bit lines GBL. Each select transistor ST includes a source region 20, a channel region 1, a drain region 22, a gate insulating film 23, and a select gate line SG. The select gate line SG functions as a gate electrode of the select transistor ST. The select transistor ST is formed of a vertical FET (field effect transistor), but may comprise any type of switching element, for example, a vertical TFT, etc.

The source region 20, the channel region 21, and the drain region 22 are stacked in this order. The source region 20 and the drain region 22 are each formed of an n-type semiconductor layer doped with a high-concentration n-type impurity. The channel region 21 is formed of a p-type semiconductor layer doped with a p-type impurity.

The gate insulating film 23 is provided on a side surface of the channel region 21. The select gate line SG is provided on a side surface of the gate insulating film 23. The two select gate lines SG sandwiching the channel region 21 from both sides in Y direction are electrically connected to each other and function as one select gate line.

The select transistor ST is also called a sheet selector (select element). The term “sheet” represents a group of memory cells selected by any one of the select gate lines SG. In FIG. 2, a group of memory cells on a plane defined by X direction and Z direction is a sheet. The pillar shaped bit line BL is provided on the drain region 22. The resistance change layer 24 is provided on the side surface of the bit line BL. In this embodiment, the resistance change layer 24 is provided on the entire side surface in Y direction of the bit line BL. The word line WL extending in X direction is provided in a region between the adjacent bit lines BL in Y direction. The portion of the resistance change layer 24 that is interposed between the bit line BL and the word line WL functions as the memory cell MC. In the example described herein, the resistance change layer 24 is provided on the entire side surface in Y direction of the bit line BL; however, the resistance change layer 24 may be provided only in a region where the bit line BL and the word line WL intersect.

Polycrystalline silicon is an example of a material that can be used for the bit line BL and the select gate line SG. A low-resistance semiconductor or metal material doped with a high-concentration impurity is an example of a material that can be used for the word line WL and the global bit line GBL. A silicon oxide (SiO₂) or a silicon nitride (SiN) is an example of a material that can be used for the gate insulating film 23.

The resistance change layer 24 is formed of, for example, hafnium oxide (HFO). The resistance change layer 24 represented by HFO transitions between at least two resistance values in a low-resistance state and a high-resistance state. For example, the resistance change layer in the high-resistance state transitions to the low-resistance state when a specified or higher voltage is applied. The resistance change layer in the low-resistance state transitions to the high-resistance state when the specified or higher current flows.

In a type of resistance change layer, the transition from the high-resistance state to the low-resistance state and the transition from the low-resistance state to the high-resistance state is performed by applying voltages of different polarities. Such an element is called a bipolar operation element. The resistance change layer 24, that performs the bipolar operation can be formed of a thin film containing a material other than HfO, such as TiO₂, ZnMn₂O₄, NiO, AlO, SrZrO₃, or Pr_{0.7}Ca_{0.3} MnO₃.

Furthermore, polycrystalline or amorphous Si, Ge, SiGe, GaAs, InP, GaP, GaInAsP, GaN, SiC, SiO, SiON, SiN, HfSiO, or AlO can be used as a material for the resistance change layer 24. A stacked layer of any of the aforementioned materials can be used for the resistance change layer 24.

The resistance change layer is formed of, for example, chalcogenide. The resistance change layer is formed of, for example, chalcogenide containing germanium (Ge) antimony (Sb), and tellurium (Te). The resistance change layer is, for example, a Ge₂Sb₂Te₅ alloy.

Furthermore, an electrode formed of Ag, Au, Ti, Ni, Co, Al, Fe, Cr, Cu, W, Hf, Ta, Pt, Ru, Zr, or Ir, or a nitride or carbide thereof may be interposed between the resistance change layer 24 and the bit line BL. Furthermore, the electrode may be formed of a material to which any of the aforementioned materials has been added to polycrystalline silicon.

With described above, the memory cells MC, each including the word line WL, the bit lines BL, and the resistance change layer 24 disposed between the word line WL and the bit line BL, are arranged in a three-dimensional matrix. In the structure of this embodiment, the word line WL and the bit lines BL form a mere line-and-space pattern. It is necessary for the word line WL and the bit line BL to be positioned only so that they intersect each other, and displacement in the word line direction and the bit line direction need not be taken into consideration. Therefore, even a very low level of positioning accuracy in the memory cell during manufacture is permissible, thereby allowing for easy manufacture of the memory device.

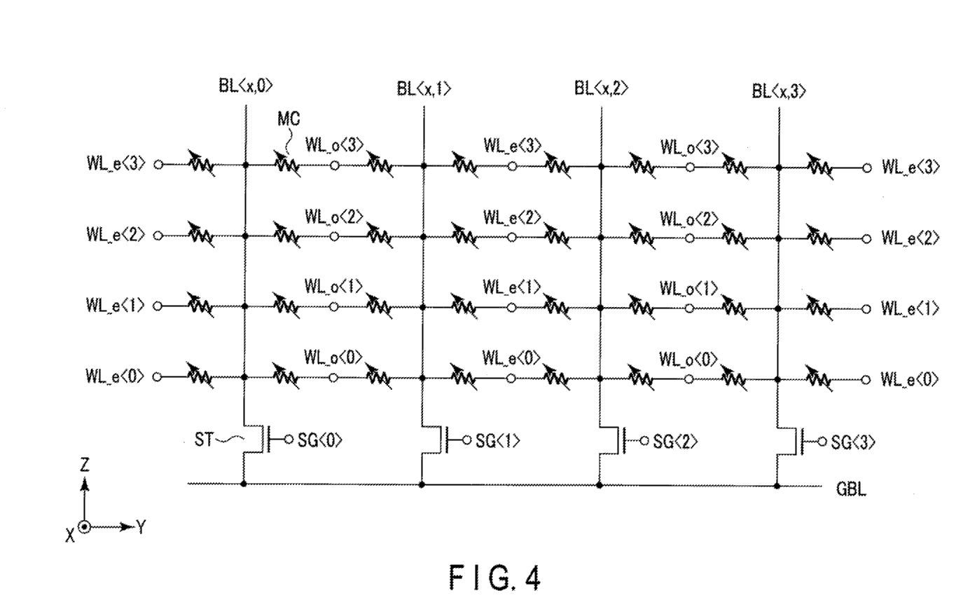

1.1.2 Circuit of Memory Cell Array 11 Now, the circuit configuration of the memory cell array 11 shown in FIG. 4 will be described. FIG. 4 is a circuit diagram (equivalent circuit diagram) of the memory cell array 11.

An even-numbered word line is expressed as “WL_e”, and an odd-numbered word line is expressed as “WL_o”. Even-numbered word lines WL_e and odd-numbered word lines WL_o are alternately arranged along Y direction. Voltages of the even-numbered word lines WL_e and the odd-numbered word lines WL_o can be independently controlled. The memory cells MC are each arranged at an intersection portion between the bit line BL and the word line WL and connected to the bit line BL and the word line WL.

The drain of the select transistor ST is connected to the bit line BL, the source thereof is connected to the global bit line GBL, and the gate thereof is connected to the select gate line SG.

FIG. 4 shows the word lines of four layers and the four bit lines as extracts. Specifically, FIG. 4 shows the word lines WL_e<0> to WL_e.<3>, the word lines WL_o<0> to WL_o<3>, the select gate lines SG<0> to SG<3>, and the bit lines BL<x, 0>to BL<x, 3>. The symbol “x” means any of the rows in Y direction.

1.2 Other Configurations of Semiconductor Memory Device

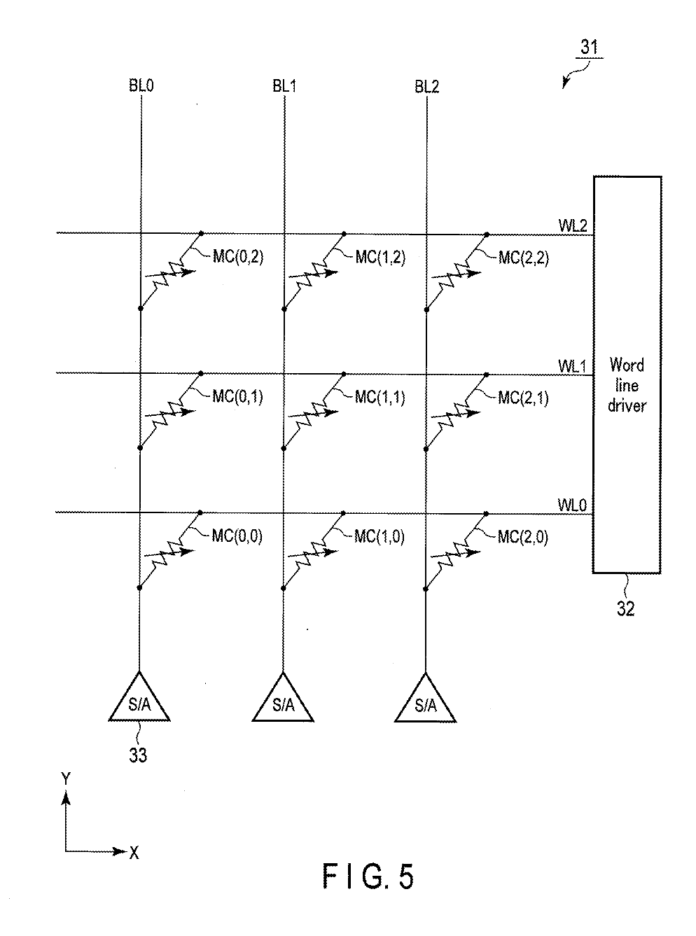

The embodiment can be applied to a cross-point type resistance-change memory described below. FIG. 5 is a circuit diagram of a memory cell array in another configuration of the semiconductor memory device according to the embodiment. A memory cell array 31 is of the cross-point type.

The word lines WL0, WL1, and WL2 extend in X direction and aligned along Y direction at intervals. The word lines WL0, WL1, and WL2 are connected to a word line driver 32. The word line driver 32 applies a voltage necessary for a reset operation, a read operation, and a set operation for data to both a select word line and a non-select word line.

Although the word lines WL0, WL1, and. WL2 are represented here, any number of word lines may be used.

The bit lines BL0, Bl1, and BL2 extend in Y direction and are aligned along X direction at intervals. Each of the bit lines BL0, Bl1, and BL2 is connected to a sense amplifier (S/A) 33. The sense amplifier 33 applies a voltage necessary for a reset operation, a read operation, and a set operation for data to a select bit line and a non-select bit line. The sense amplifier 33 senses and amplifies data read out from the variable resistive element to the bit line BL in a verification read in either a reset operation or a read operation. Although the bit lines BL0, BL1, and BL2 are represented here, any number of bit lines may be used.

The memory cells MC (0, 0), (0,1), . . . (2,2) are each arranged at an intersection between the word line WL0, WL1 or WL2 and the bit line BL0, BL1 or BL2. Thus, the resistance change memory has a cross-point type memory cell array structure. The memory cell MC includes a variable resistive element, which will be described later. The memory cell array may have a stacked structure, in which a plurality of memory cell arrays 31 shown in FIG. 5 are stacked.

1.3 Operation of Semiconductor Memory Device

Next, an operation of the semiconductor memory device according to the present embodiment will be described. The embodiment is applicable to both the semiconductor memory device 10 and the semiconductor memory device including the memory cell array 31 described above. In the following, the semiconductor memory device 10 is described as an example.

1.3.1 Basic Operation

The memory cell MC is capable of storing one bit data, and stores data in accordance with its own resistance state. An operation of setting the memory cell MC to a high-resistance state—or OFF state—(that is, an operation of transitioning from a low-resistance state to a high-resistance state) is called a reset operation. An operation of setting the memory cell MC to a low-resistance state—or ON state—(that is, an operation of transitioning from a high-resistance state to a low-resistance state) is called a set operation.

FIG, 6 is a diagram for explaining voltages in a reset operation, a set operation, and a read operation. A select global bit line is represented as “GBL_s”, a non-select global bit line as “GBL_u”, a select word line as “WL_s”, a non-select word line as “WL_u”, a selected select gate line as “SG_s”, and a non-selected select gate line as “SG_u”. In the following, the reset operation, the set operation, and the read operation will be described in this order.

(Reset Operation)

In the reset operation, to store data in the memory cell MC, the controller 17 applies a reset voltage Vw (>0V) to the select global bit line GBL_s, and applies a voltage Vwf (=Vw/2) to the non-select global bit line GBL_u and the non-select word line WL_u, so that the voltage applied to a half-selected cell can be half of the voltage applied to the select cell. Furthermore, the controller 17 applies 0V to the select word line WL s and the non-selected select gate line SG_u, and applies a reset gate voltage Vg_w (>0V) to the selected select gate line SG_s. The reset gate voltage Vg_w is a voltage which turns on the select transistor ST in the reset operation.

As a result, the select transistor ST connected to the select bit line BL is turned on, and the reset voltage Vw is transferred to the select memory cell MC through the select global hit line GBL_s. On the other hand, the voltage 0V is transferred to the select memory cell MC through the select word line WL_s. Thus, a difference in potential of Vw occurs between the both ends of the variable resistive element, so that the resistance state of the memory cell MC is set to the high-resistance state. As a result, the data in the memory cell. MC is reset.

(Set Operation)

In the set operation, to store data in the memory cell MC, the controller 17 applies a voltage Ve (>0V) to the select word line WL_s in consideration of a bipolar operation of the memory cell MC, and applies a voltage Vef (=Ve/2) to the non-select global bit line GBL_u and the non-select word line WL_u, so that the voltage applied to a half-selected cell can be half of the voltage applied to the select cell. Furthermore, the controller 17 applies 0V to the select global bit line GBL_s and the non-selected select gate line SG_u, and applies a set gate voltage Vg_e to the selected select gate line SG_s. The set gate voltage Vg_e is a voltage to turn on the select transistor ST in the set operation.

As a result, the select transistor ST connected to the select bit line BL is turned on, and the set voltage Ve is transferred to the select memory cell MC through the select word line WL_s. On the other hand, the voltage 0V is transferred to the select memory cell MC through the select global bit line GBL_s. Thus, a difference in potential of Ve occurs between the both ends of the variable resistive element, so that the resistance state of the memory cell MC is set to the low-resistance state. As a result, the data in the memory cell MC is set.

(Read Operation)

In the read operation to read data from the memory cell MC, the controller 1 applies a read voltage Vr to the select global bit line GBL_s and the non-select global bit line GBL_u. Furthermore, the controller 17 applies 0V to the select word line WL_s and the read voltage Vr to the non-select word line WL_u. The controller 17 also applies a read gate voltage Vg_r to the selected select gate line SG_s, and applies 0V to the non-selected select gate line SG_u. The read gate voltage Vg_r is a voltage to turn on the select transistor ST in the read operation.

As a result, the select transistor ST connected to the select bit line BL is turned on, and the read voltage Vr is transferred to the select memory cell MC through the select global bit line GBL_s. On the other hand, the voltage 0V is transferred to the select memory cell MC through the select word line WL_s. The current flowing through the select memory cell MC varies depending on the resistance state of the select memory cell MC. Data stored in the select memory cell MC is determined by sensing the current flowing through the select global bit line GBL_s via the sense amplifier 15.

1.3.2 Operation of Embodiment

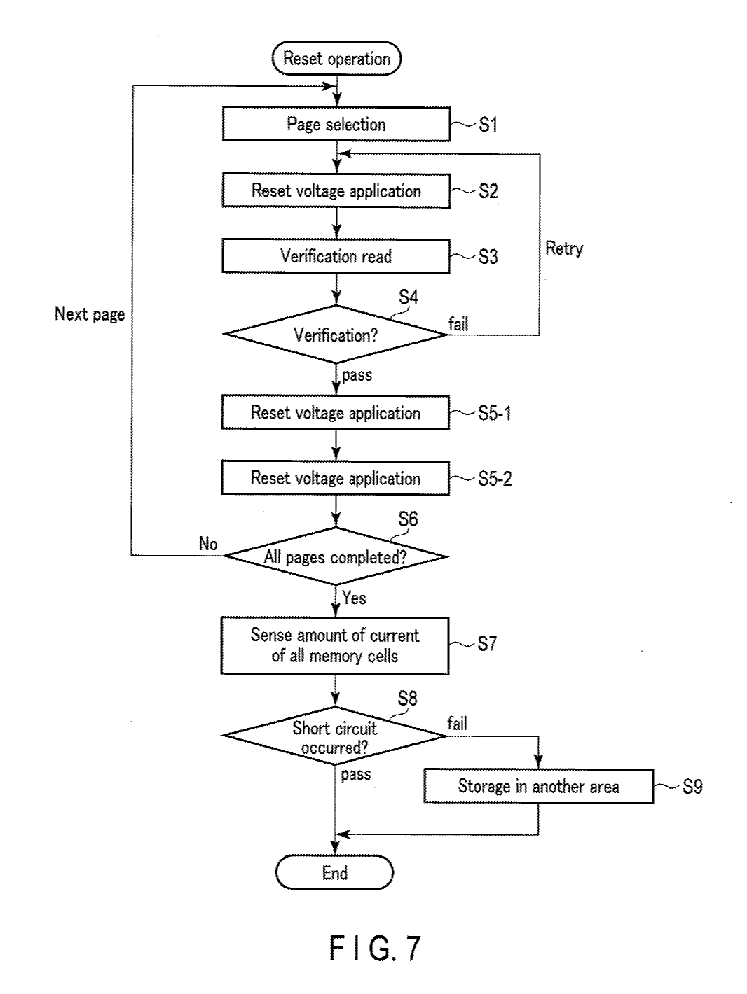

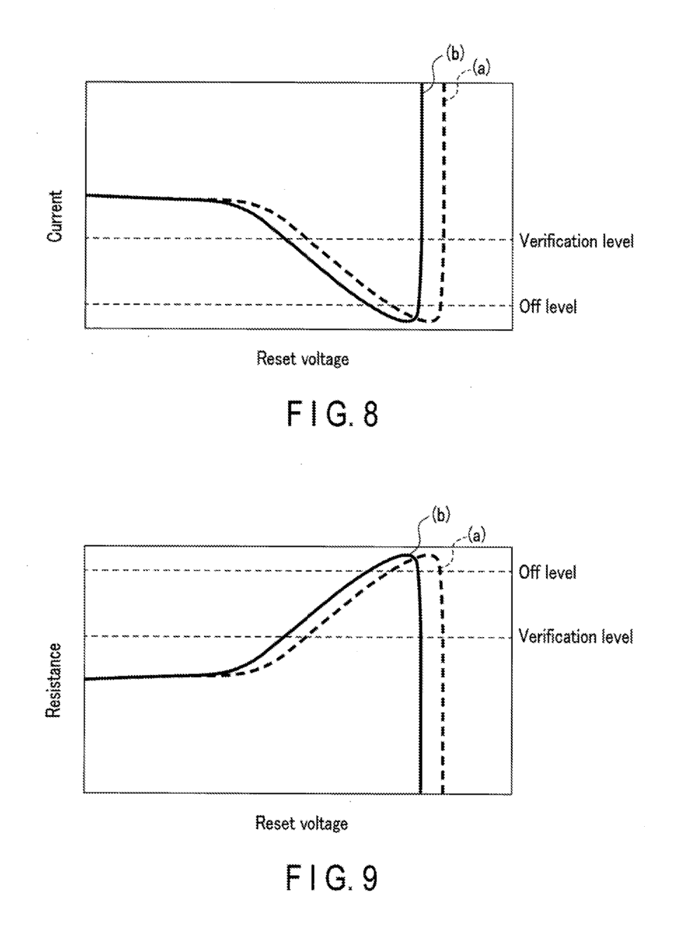

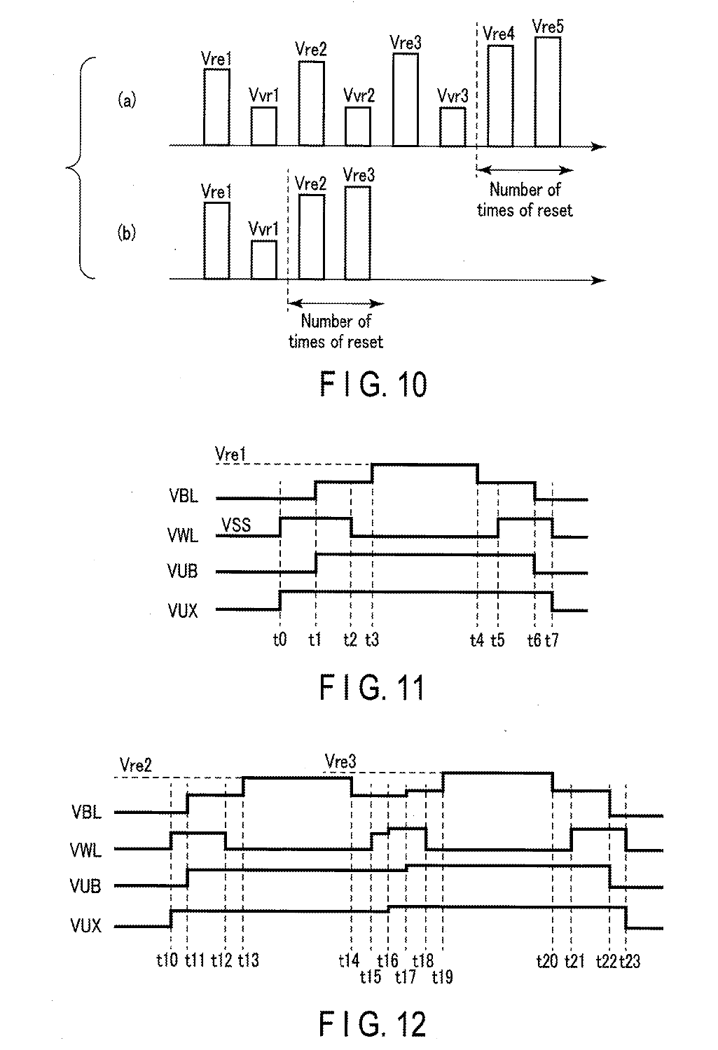

Next, a reset operation the embodiment will be described. FIG. 7 is a flowchart showing the reset operation of the embodiment. The reset operation shown in FIG. 7 is controlled by the controller 17. The reset operation includes an operation of applying the reset voltage to the memory cell. MC as a reset target, a verification read for the memory cell as the reset target after the reset voltage is applied and a verification of the verification read (hereinafter referred to as verification). The verification is an operation to verify whether the memory cell MC as the reset target transitions to a resistance state of a verification level, after the reset voltage is applied, The verification is carried out by detecting whether the current flowing through the memory cell MC as the reset target becomes equal to or less than the current value of the verification level.

FIG. 8 shows a change in current in a verification read by application of a reset voltage. FIG. 9 shows a change in resistance in a memory cell by application of the reset voltage. In the embodiment, during the verification read, when the current flowing through the memory cell MC becomes equal to or less than the current value of the verification level shown in FIG. 8, that is, when the resistance of the memory cell MC becomes equal to or higher than the resistance of the verification level shown in FIG. 9, it is determined that the verification is passed. On the other hand, when the resistance of the memory cell MC is lower than the resistance of the verification level, it is determined that the verification has failed. The set resistance of the verification level is lower than the resistance when the memory cell is off. In other words, the set resistance is lower than theresistance when the memory cell is determined to be in the high-resistance state.

In FIG. 8, (a) represents a reset voltage in the reset operation shown in FIG, 10 (a) to be described later, and a current in a verification read. In FIG. 8, (b) represents a reset voltage in the reset operation shown in FIG. 10 (b), and a current in a verification read. In FIG. 9, (a) represents a reset voltage in the reset operation shown in FIG. 10 (a), and a resistance of the memory cell MC in a verification read. In FIG. 9, (b) represents a reset voltage in the reset operation shown in FIG. 10 (b), and a resistance of the memory cell. MC in a verification read.

In the array structure of the embodiment, a voltage drop in wirings (the bit line BL and the word line WL) varies considerably depending on the resistance state of an enormous number of memory cells connected to the same bit line BL and the same word line WL. In other words, a difference in reset voltage shown in FIG. 8 and FIG. 9 may occur, primarily depending on the resistance states in surrounding memory cells and not on a variation in characteristics of the respective memory cells). The embodiment corrects the difference in reset voltage due to the resistance states in the surrounding memory cells by ascertaining a start voltage of the reset.

After the reset voltage is applied, application of the reset voltage and verification are repeated, until the verification is passed. When the verification is passed, application of the reset voltage is performed once or a plurality of times. After the verification is passed, no further verification is carried out. The number of times the reset voltage is applied to the memory cell MC after the verification is passed is referred to as the number of times of reset.

The reset operation of the embodiment will be described below with reference to FIG. 7.

First, the controller 17 selects a target page for the reset operation (step S1). For example, the reset operation is carried out in page units. A page may include a plurality of memory cells connected to a single word line in the sheet mentioned above.

Next, the reset voltage is applied to the memory cell as a reset target in the selected page (step S2). Then, a verification read to verify whether or not the memory cell transitions to the resistance state of the verification level is carried out by the application of the reset voltage. In the verification read, the sense amplifier 15 senses whether or not the resistance of the memory cell reaches the resistance value of the verification level or higher by the application of the reset voltage (step S3).

Then, the result of the verification read is determined (step S4). Specifically, if the resistance of the memory cell is equal to or higher than the resistance value of the verification level (pass in step S4), it is determined that the verification is passed and the processing proceeds to step S5-1. On the other hands, if the resistance of the memory cell is lower than the resistance value of the verification level (fail in step S4), it is determined that the verification fails and the processing returns to step S2, and the processing in steps S2 to S4 is repeated. Namely, the application of the reset voltage and the verification read are repeated for the memory cell as the reset target, until the verification is passed. The repetition of the application of the reset voltage and the verification read will be described later in detail.

When the verification is passed and the processing proceeds to step S5-1, reset voltage is applied to the memory cell MC as the reset target once or a plurality of times (steps S5-1 and S5-2). In the period in which the reset voltage is applied after the verification is passed, no further verification including a verification read is carried out. The application of the reset voltage after the verification is passed will be described later in detail.

Then, the processing proceeds to step S6, and it is determined whether or not the reset operation was completed for all the target pages of the reset operation (step S6). If it is determined that the reset operation has not been completed for all the target pages (No in step S6), the processing returns to step S1 and the processing in steps S1 to S6 is repeated.

In step S6, if the reset operation has been completed for all the target pages (Yes in step S6), the voltage is applied to all memory cells of the reset target to sense the amount of current (step S7). Subsequently, from the amount of current in all memory cells, it is determined whether dielectric breakdown occurs in all memory cells of the reset target, that is, whether a short circuit occurs between the bit line BL and the word line WL (step S8). If a short circuit occurs, the amount of current in all memory cells is considerably greater than the amount of current of the verification level. For example, when the amount of current is greater than a predetermined amount, it is determined that a short circuit occurs. If a short circuit does not occur (pass in step S8), the reset operation is ended. If a short circuit occurs (fail in step S8), it is determined that the reset operation for a target page fails, the information is stored in another area of the memory cell and the reset operation is ended.

If the word line WL selected in step S1 extends in a plurality of layers, occurrence of a short circuit is confirmed, for example, as follows. In the read conditions shown in FIG. 6, all layers including at least the word lines WL to which data is written are set to the voltage of WL_s, and a read operation is performed. At this time, the current flowing through the global bit line GBL is measured, and if the amount of current is greater than a threshold value, it is determined that a short circuit occurs in any of the bits, that is, in any of the memory cells. As an example, the amount of current may be read from the resistances of the global bit line GBL, the bit line BL, the memory cell, and the word line WL added together.

Next, operations in steps S2 to S5-2 shown in FIG. 7 will be described with reference to FIG. 10. In steps S2 to S5-2, the application of a reset voltage, and the verification read and the verification are repeated. When the verification is passed, the application of the reset voltage, without the verification, is repeated for the number of times of reset.

FIG. 10 is a diagram showing a reset voltage and a verification voltage applied to the memory cell MC as the reset target in the reset operation. The verification voltage is a voltage applied to the memory cell MC after the reset voltage is applied during the verification read. In FIG. 10, (a) represents a case in which the application of the reset voltage and the verification are repeated three times, and then the verification is passed. In FIG.10, (b) represents a case in which the application of the reset voltage and the verification are performed once, and then the verification is passed.

The reset operation of (a) shown in FIG. 10 will be described below. A reset voltage Vre1 is applied to the memory cell MC. Then, the verification voltage Vvr1 is applied to the memory cell MC to perform the verification.

Since the verification is not passed at this time, a reset voltage Vre2 is subsequently applied to the memory cell MC. The reset voltage Vre2 is equal to the reset voltage Vre1 plus a voltage ΔV. Then, the verification voltage Vvr2 is applied to the memory cell MC to perform the verification.

Since the verification is not passed at this time, a reset voltage Vre3 is subsequently applied to the memory cell MC. The reset voltage Vre3 is equal to the reset voltage Vre2 plus a voltage ΔV. Then, the verification voltage Vvr3 is applied to the memory cell MC to perform. the verification.

At this time, the verification by the verification voltage Vvr3 is passed. Then, the application of the reset voltage to the memory cell MC is repeated for the number of times of reset. Thus, a reset voltage Vre4 is applied to the memory cell MC. The reset voltage Vre4 is set based on the reset voltage Vre3. Specifically, the reset voltage Vre4 is a voltage obtained by adding the voltage ΔV to the reset voltage Vre3. Furthermore, a reset voltage Vre5 is applied to the memory cell MC. The reset voltage Vre5 is a voltage obtained by adding the voltage ΔV to the reset voltage Vre4. In this embodiment, the number of times of reset is given as two, but may be one, three or more.

The reset operation of (b) shown in FIG. 10 will be described below. A reset voltage Vre1 is applied to the memory cell MC. Then, the verification voltage Vvr1 is applied to the memory cell MC to perform the verification

At this time, the verification by the verification voltage Vvr1 is passed. Then, the application of the reset voltage to the memory cell MC is repeated for the number of times of reset. Thus, a reset voltage Vre2 is applied to the memory cell MC. The reset voltage Vre2 is set based on the reset voltage Vre1. Specifically, the reset voltage Vre2 is a voltage obtained by adding the voltage ΔV to the reset voltage Vre1. Furthermore, a reset voltage Vre3 is applied to the memory cell MC. The reset voltage Vre3 is a voltage obtained by adding the voltage ΔV to the reset voltage Vre2. In this embodiment, the number of times of reset is given as two, but may be one, three or more.

As described above, after the verification by the verification voltage is passed, the reset voltage applied on the first time to the memory cell MC is set on the basis of the reset voltage at the time when the verification is passed. In other words, the first reset voltage is a reset voltage obtained by adding the voltage ΔV to the reset voltage at the time when the verification is passed (Vre3+ΔV or Vre1+ΔV). Furthermore, the reset voltage applied on the second time to the memory cell is a reset voltage obtained by adding the voltage ΔV to the first reset voltage (Vre4+ΔV or Vre2+ΔV). If the reset voltage is further applied, a voltage obtained by adding the voltage ΔV to the reset voltage of the former time is used.

The number of times of reset is stored in a storage circuit in the semiconductor memory device 10, for example, in a ROM region, etc. in the memory cell array 11. After the verification is passed, the reset voltage is applied once or a plurality of times in accordance with information relating to the number of times of reset stored in the ROM region.

The number of times of reset is determined in accordance with the properties, or the like, of the memory cell MC. For example, the number of times of reset is determined when the memory cell is evaluated before shipment, and stored in the ROM region in the memory cell array 11. The controller 17 reads out the number of times of reset from the ROM region when the semiconductor memory device 10 is operating. The controller 17 executes the application of the reset voltage in accordance with the number of times of reset that is read out.

The ROM region also stores other information relating to the reset operation, for example, an amplitude (pulse amplitude) of the reset voltage, a pulse width, the number of retries, a current value of the verification level, a resistance value, etc. The number of retries is the number of times of the application of a reset voltage and the verification, which are repeated if the verification is not passed.

As described above, the reset voltage applied to the memory cell MC, after the verification is passed, is set on the basis of the reset voltage used when the verification is passed. If the application of the reset voltage is repeated, a step-up operation of increasing the previous reset voltage by the voltage ΔV is performed. The number of times of application of the reset voltage, performed after the verification is passed, is determined on the basis of information stored in advance in the ROM region or the like.

The reset voltage (or the reset pulse) repeatedly applied as mentioned above is set in any discretionary way; for example, the pulse widths may be equally magnified while the amplitudes of the reset voltages Vre1 to Vre5 are the same, or the amount of the pulse amplitude may be gradually increased to satisfy the equation Vre(n+1)−Vren=n×Δ. However, regardless of how many times the verification is passed, it is desirable that the conditions of the reset pulse applied n-th time are the same, from the viewpoint of controllability using the controller 17. The symbol n is a natural number not less than 1.

The current value of the verification read after application of the reset voltage may vary depending on the state of the memory cell array, even if the memory cell MC is the same. This results from the fact that the magnitude of a sneak current varies depending on the resistance state of memory cells surrounding the target memory cell MC in the memory cell array, and the voltage drop due to the wiring resistance of the word line and the bit line also varies. In the case of a memory cell MC being far from the word line decoder 12 or the bit line decoder 14, it is known that the voltage drop of the reset voltage is increased by the wiring resistance. Therefore, the reset voltage may be set to a high value in advance. The information as described above can also be stored in the ROM region or the like in the evaluation before shipment.

Next, voltage waveforms of the bit line BL and the word line WL in the case of applying the reset voltage will be described with reference to FIG. 11.

FIG. 11 is a waveform diagram showing voltages of the bit line BL and the word line WL when the reset voltage is applied. A voltage VBL represents a voltage of the select bit line BL, and a voltage VWL represents a voltage of the select word line WL. A voltage VUB represents a voltage of the non-select bit line BL, and a voltage VUX represents a voltage of the non-select word line WL. The diagram shows voltage waveforms of the bit line BL and the word line WL when the reset voltage Vre1 is applied to the memory cell MC.

First, at time to, voltages of all word lines WL, namely, the select word line voltage VWL and the non-select word line voltage VUX are set to Vre1f(=Vre1/2), which is half of the reset voltage Vre1. At time t1, voltages of all bit lines BL, namely, the select bit line voltage VBL and the non-select bit line voltage VUB are set to Vre1f, which is half of the reset voltage Vre1. At time t2, the select word line voltage VWL is set to a reference voltage VSS (=0V). At time t3, the select bit line voltage VBL is set to the reset voltage Vre1. Thus, application of the reset. voltage Vre1 to the memory cell MC is commenced.

Then, at time t4, the select bit line voltage VBL is set to the voltage Vre1f. Thus, the application of the reset voltage is ended. Furthermore, at time t5, the select word line voltage VWL is set to the voltage Vre1f. At time t6, the select bit line voltage VBL and the non-select bit line voltage VUB are set to the reference voltage VSS. At time t7, the select word line voltage VWL and the non-select word line voltage VUX are set to the reference voltage VSS. Thus, the reset operation is ended.

The select bit line voltage VBL, the non-select bit line voltage VUB, the select word line voltage VWL, and the non-select word line voltage VUX are set so that the sneak current can be minimized. For example, those voltages are set to Vre1f (=Vre1/2) which is half of the reset voltage Vre1, as described above.

The read operation, depending on the sensing system used in the embodiment, can be set discretionarily. If the reset voltage Vre1 is replaced by a read voltage Vread, a voltage application sequence similar to that illustrated in FIG. 11 may be used.

In this case, the Vre1f (=Vre1/2) used during the application of the reset voltage is much different from a voltage Vread2, half of the read voltage Vread used during the verification read. Therefore, to perform the verification read after the application of the reset voltage, time is needed to charge the non-select bit line EL and the non-select word line WL.

However, if only the application of the reset voltage is performed without performing the verification read, it is only necessary to charge the select bit line BL by the increased amount ΔV of the reset voltage. Therefore, the charging time for the word line WL and the bit line BL can be set to a short period. For example, the time required from the application of the reset voltage Vre2 to the application of the reset voltage Vre3 can be reduced by using the voltage waveforms as illustrated in FIG. 12.

FIG. 12 shows voltages applied to the word line WL and the bit line BL when the reset voltage Vre2 and Vre3 are consecutively applied in the embodiment. From time t10 to time t15, the application of the reset voltage Vre2 is completed. Then, at time t16, the select word line voltage VWL and the non-select word line voltage VUX are boosted from the voltage Vre2f (=Vre2/2), which is half of the reset voltage Vre2, to the voltage Vre3f (=Vre3/2), which is half of the reset voltage Vre3. Furthermore, at time t17, the select bit line voltage VBL and the non-select bit line voltage VUB are boosted from the voltage Vre2f to the voltage Vre3f. At this time, if the difference between the voltage Vre2f and the voltage Vre3f is small the time required for boosting is short.

Then, at time t19, the select bit line voltage VBL is set to the reset voltage Vre3. Thus, the application of the reset voltage is started. Then, at time t20, the select bit line voltage VBL is set to the voltage Vre3f. Thus, the application of the reset voltage is ended. Furthermore, at time t21, the select word line voltage VWL is set to the voltage Vre3f. At time t22, the select bit line voltage VBL and the non-select bit line voltage VUB are set to the reference voltage VSS. At time t23, the select word line voltage VWL and the non-select word line voltage VUX are set to the reference voltage VSS. Thus, the reset operation is ended.

If the difference between the reset voltage Vre2 and the reset voltage Vre3 is small, and the voltage Vre2f and the voltage Vre3f are not substantially changed, the time required for boosting can be shorter. Otherwise, if the reset voltage. Vre2f and the reset voltage Vre3f are set as the same, the time required for boosting can be even further shortened.

1.4 Advantages of Embodiment

According to the embodiment, in the reset operation, the application of the reset voltage and the resistance state of the memory cell after application of the reset voltage are verified. In other words, verification is carried out to sense whether the value of the current flowing through the memory cell after the application of the reset voltage is equal to or lower than the value of the current of the verification level. The value of the current of the verification level is greater than the value of the current at which the memory cell MC is determined to be a high-resistance state (OFF state). If the verification fails, the application of the reset voltage and the verification are repeated. Then, when the verification is passed, the application of the reset voltage to the memory cell MC is executed a preset number of times stored in the memory circuit (for example, the ROM region) in the semiconductor memory device 10.

The reset voltage to be applied to the memory cell MC after the verification is passed is set on the basis of the reset voltage applied when the verification is passed. By applying the reset voltage a preset number of times after the verification is passed, the low-resistance state of the memory cell MC can be transitioned to a high-resistance. state.

As a result, in the embodiment, the current value for sensing the high-resistance state of the memory cell can be heightened. Furthermore, after the verification is passed, only the application of the reset voltage is performed without the verification. Therefore, the time required for the reset operation can be shortened. Moreover, when the reset voltage is repeatedly applied, the voltage ΔV added to the reset voltage can be set to a low value. Therefore, the excess application of the reset voltage can be suppressed.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A semiconductor memory device comprising:
a word line;
a bit line crossing the word line;
a memory cell provided at an intersection between the word line and the bit line and including a variable resistive element;
a controller configured to control a voltage application and a read operation with respect to the memory cell;
wherein the controller performs a first operation of applying a first voltage to the memory cell, and a first verification of verifying whether a resistance of the memory cell becomes equal to a first value or greater after the first operation, and
performs a second operation of applying to the memory cell a second voltage set based on the first voltage, when the resistance of the memory cell becomes equal to the first value or greater in the first verification.

2. The semiconductor memory device according to claim 1, wherein the first operation, the first verification, and the second operation performed by the controller is a reset operation designed to transition a memory cell in a low-resistance state to a high-resistance state.

3. The semiconductor memory device according to claim 2, wherein in the first verification, a third voltage is applied to the memory cell to verify whether the resistance of the memory cell becomes equal to the first value or greater, and the first value is smaller than a resistance of the memory cell in the high-resistance state.

4. The semiconductor memory device according to claim. 1, further comprising a memory that stores information on the second operation,
wherein the controller performs the second operation based on the information stored in the memory, when the resistance of the memory cell becomes equal to the first value or greater in the first verification.

5. The semiconductor memory device according to claim 4, wherein the information includes the number of times the second operation is to be executed; and
the controller executes the second operation in accordance with the number of times.

6. The semiconductor memory device according to claim 1, wherein when the second operation is repeated a plurality of times, a voltage that is a predetermined voltage higher than the second voltage used in the second operation of a previous time is applied to the memory cell in the second operation of a subsequent time.

7. The semiconductor memory device according to claim 1, further comprising a memory that stores information on the first verification, wherein the controller performs the first verification based on the information stored in the memory, after the first operation.

8. The semiconductor memory device according to claim 1, wherein when the resistance of the memory cell is less than the first value in the first verification, the first operation and the first verification are repeated, and a voltage that is a predetermined voltage higher than the first voltage used in the first operation of a previous time is applied to the memory cell in the first operation of a subsequent time.

9. The semiconductor memory device according to claim 1, wherein the controller applies a voltage to the memory cell in which the second operation is executed, and determines whether or not a current flowing through the bit line is equal to a second value or greater.

10. A semiconductor memory device comprising:
a word line;
a bit line crossing the word line;
a memory cell provided at an intersection between the word line and the bit line and including a variable resistive element;
a controller configured to control a voltage application and a read operation with respect to the memory cell;
wherein the controller performs a first operation of applying a first voltage to the memory cell, and a first verification of verifying whether a read current generated by the read operation of the memory cell becomes equal to a first value or less after the first operation, and
performs a second operation of applying to the memory cell a second voltage set based on the first voltage, when the read current of the memory cell becomes equal to the first value or less in the first verification.

11. The semiconductor memory device according to claim 10, wherein the first operation, the first verification, and the second operation performed by the controller is a reset operation designed to transition a memory cell in a low-resistance state to a high-resistance state.

12. The semiconductor memory device according to claim 10, wherein in the first verification, a third voltage is applied to the memory cell to verify whether a current flowing through the bit line becomes equal to the first value or less, and the first value is greater than a current flowing through the bit line when the third voltage is applied to the memory cell in the high-resistance state.

13. The semiconductor memory device according to claim 10, further comprising a memory that stores information on the second operation,
wherein the controller performs the second operation based on the information stored in the memory, when the read current of the memory cell becomes equal to the first value or less in the first verification.

14. The semiconductor memory device according to claim 13, wherein the information includes the number of times the second operation is to be executed; and
the controller executes the second operation in accordance with the number of times.

15. The semiconductor memory device according to claim 10, wherein when the second operation is repeated a plurality of times, a voltage that is a predetermined voltage higher than the second voltage used in the second operation of a previous time is applied to the memory cell in the second operation of a subsequent time.

16. The semiconductor memory device according to claim 10, further comprising a memory that stores information on the first verification,
wherein the controller performs the first verification based on the information stored in the memory, after the first operation.

17. The semiconductor memory device according to claim 10, wherein when the read current of the memory cell is greater than the first value in the first verification, the first operation and the first verification are repeated, and a voltage that is a predetermined voltage higher than the first voltage used in the first operation of a previous time is applied to the memory cell in the first operation of a subsequent time.

18. The semiconductor memory device according to claim 10, wherein the controller applies a voltage to the memory cell in which the second operation is executed, and determines whether or not a current flowing through the bit line is equal to a second value or greater.
